(19) United States
(12) Patent Application Publication
(10) Pub. No.: US 2025/0363258 A1
(43) Pub. Date: Nov. 27, 2025

(54) SATURATION EFFECT-BASED SYNCHRONOUS MACHINE ELECTROMAGNETIC TRANSIENT MODELING METHOD, SYSTEM AND DEVICE

(71) Applicants: ELECTRIC POWER RESEARCH INSTITUTE, CHINA SOUTHERN POWER GRID, Guangzhou, Guangdong (CN); CHINA SOUTHERN POWER GRID COMPANY LIMITED, Guangzhou, Guangdong (CN)

(72) Inventors: Yinsheng SU, Guangzhou, Guangdong (CN); Xiaoshan WU, Guangzhou, Guangdong (CN); Sijia TU, Guangzhou, Guangdong (CN); Haicheng YAO, Guangzhou, Guangdong (CN); Bao LI, Guangzhou, Guangdong (CN); Ligang ZHAO, Guangzhou, Guangdong (CN); Tinghui ZHOU, Guangzhou, Guangdong (CN); Qin GAO, Guangzhou, Guangdong (CN); Guanbiao HUANG, Guangzhou, Guangdong (CN); Hongyue ZHEN, Guangzhou, Guangdong (CN); Yuan XU, Guangzhou, Guangdong (CN); Changxiang WANG, Guangzhou, Guangdong (CN); Zhenyu MAO, Guangzhou, Guangdong (CN); Xuepeng MOU, Guangzhou, Guangdong (CN)

(73) Assignees: ELECTRIC POWER RESEARCH INSTITUTE, CHINA SOUTHERN POWER GRID, Guangzhou, Guangdong (CN); CHINA SOUTHERN POWER GRID COMPANY LIMITED, Guangzhou, Guangdong (CN)

(21) Appl. No.: 18/874,672

(22) PCT Filed: Sep. 22, 2022
(86) PCT No.: PCT/CN2022/120475

§ 371 Date: Dec. 13, 2024

(30) Foreign Application Priority Data
Jun. 15, 2022 (CN) 202210674163.2

(51) Int. Cl. G06F 30/17; G06F 17/16

(52) U.S. Cl. CPC G06F 30/17; G06F 17/16

(57) ABSTRACT

A saturation effect-based synchronous machine electromagnetic transient modeling method, system and device. In the method, by predicting a first rotor angular velocity, a first rotor angle, a first current q component, a first current d component, a first flux linkage turning point d component, a first flux linkage turning point q component and flux linkage turning data of a synchronous machine, analysis processing is performed to obtain a corresponding second current q component, second current d component, second rotor angular velocity, second rotor angle, stator flux linkage d component and stator flux linkage q component.

The present application claims priority to Chinese Patent Application No. 202210674163.2, titled “METHOD AND SYSTEM FOR MODELING ELECTROMAGNETIC TRANSIENTS OF SYNCHRONOUS MOTOR BASED ON MAGNETIC SATURATION, AND DEVICE”, filed on Jun. 15, 2022, with the China National Intellectual Property Administration, which is incorporated herein by reference in its entirety.

### FIELD

The present disclosure relates to the technical field of electromagnetic transients, and in particular to a method and a system for modeling electromagnetic transients of a synchronous motor based on magnetic saturation, and a device.

### BACKGROUND

Rapid promotion and application of new energy and direct-current transmission, especially flexible direct-current transmission, engenders a new trend of performing simulation on electromagnetic transients of large power grids. Experts are dedicating their research to a significant improvement of efficiency of simulating electromagnetic transient models and algorithms while ensuring accuracy.

Rotating motor is an important electric component in electromagnetic transient simulation. Magnetic saturation of rotating motor has an impact on power flow, steady-state stability, transient stability, and electromagnetic transients. The magnetic saturation of the rotating motor has nonlinear characteristics, and thus it is exceedingly difficult to simulate it accurately. Modeling and simulating the rotating motor with consideration of the magnetic saturation is crucial for accuracy and efficiency of simulating electromagnetic transients of an integral power system, especially one with many new energy sources.

### SUMMARY

A method and a system for modeling electromagnetic transients of a synchronous motor based on magnetic saturation, and a device, are provided according to embodiments of the present disclosure. Addressed is a technical issue that modeling rotating motors under magnetic saturation in conventional software for electromagnetic transient simulation has low accuracy and low efficiency.

Following technical solutions are thus provided according to embodiments of the present disclosure.

A method for modeling electromagnetic transients of a synchronous motor based on magnetic saturation is provided according to an embodiment of the present disclosure. The method comprises: step S1, predicting a first rotor angular velocity, a first rotor angle, a first quadrature-axis component (q-component) of an armature current, a direct-axis component (d-component) of the armature current, a first d-component of magnetic flux linkage at a knee point of a magnetic-flux-linkage curve, and a first q-component of magnetic flux linkage at the knee point, of the synchronous motor at a given moment through linear extrapolation, and obtaining magnetic flux linkage at the knee point indicating transition between an unsaturated state and a saturated state of the synchronous motor; step S2, determining a first equation of Norton equivalent circuit for simulating the synchronous motor according to the first q-component of the armature current and the first current d-component of the armature current, and transforming the first equation of Norton equivalent circuit expressed in a direct-quadrature-zero (dq0) reference frame into a second equation of Norton equivalent circuit expressed in a three-phase (abc) reference frame through coordinate transformation; step S3, determining an equivalent conductance matrix, which is an inverse of an equivalent resistance matrix in the second equation of Norton equivalent circuit, and solving a network conductance matrix, through substituting the determined equivalent conductance matrix into the network conductance matrix, to obtain three phase-voltages at ports of the synchronous motor; step S4, determining, according to the three phase-voltages, a second q-component and a second d-component of the armature current of the synchronous motor and a rotor current of the synchronous motor, and determining a d-component of a stator magnetic flux linkage, a q-component of the stator magnetic flux linkage, and magnetic flux linkage of an air gap, of the synchronous motor according to the second q-component of the armature current, the second d-component of the armature current, the first d-component of magnetic flux linkage at the knee point, and the first q-component of magnetic flux linkage at the knee point; step S5, in response to the magnetic flux linkage of the air gap being less than or equal to an air-gap magnetic-flux-linkage threshold, solving a mechanical system equation, through substituting the second q-component of the armature current, the second d-component of the armature current, the d-component of the stator magnetic flux linkage, and the q-component of the stator magnetic flux linkage into the mechanical system equation, to obtain a second rotor angular velocity and a second rotor angle of the synchronous motor, and determining a second d-component and a second q-component of magnetic flux linkage at the knee point of the synchronous motor according to the d-component of the stator magnetic flux linkage, the q-component of the stator magnetic flux linkage, and the magnetic flux linkage at the knee point; step S6, determining absolute differences between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively, and returning to the step S1 for a next time step in response to each of the absolute differences being smaller than a respective difference threshold of said absolute difference.

In an embodiment, the method further comprises: returning to the step S4 in response to any of the absolute differences being not smaller than the respective difference threshold of said absolute difference.

In an embodiment, determining the second d-component and the second q-component of magnetic flux linkage at the knee point of the synchronous motor according to the d-component of the stator magnetic flux linkage, the q-component of the stator magnetic flux linkage, and the magnetic flux linkage at the knee point comprises: determining a d-component of an air-gap magnetic flux linkage and a q-axis component of the air-gap magnetic flux linkage according to parameters of the synchronous motor, the first d-component of magnetic flux linkage at the knee point, the first q-component of magnetic flux linkage at the knee point, the second q-component of the armature current, and the second d-component of the armature current; determining a deflection angle of magnetic flux linkage at the knee point through an inverse trigonometric function according to a ratio of the q-component of the air-gap magnetic flux linkage to the d-component of the air-gap magnetic flux linkage; and determining the second d-component of magnetic flux linkage at the knee point and the second q-component of magnetic flux linkage at the knee point through a trigonometric function according to the magnetic flux linkage at the knee point and the deflection angle of magnetic flux linkage at the knee point.

In an embodiment, the method further comprises: in response to the magnetic flux linkage of the air gap being greater than or equal to an air-gap magnetic-flux-linkage threshold, correcting the q-component of the air-gap magnetic flux linkage, the d-component of the air-gap magnetic flux linkage, and the magnetic flux linkage of the air gap according to a saturation correction parameter to update the d-component of the stator magnetic flux linkage and the q-component of the stator magnetic flux linkage.

In an embodiment, the mechanical system equation is:

$$\begin{matrix}{T}_{gen} = \frac{p}{2} ( {λ}_{d} {i}_{s 2}^{q} - {λ}_{q} {i}_{s 2}^{d} ) \\ ω = \frac{d θ}{dt} \\ J \frac{d ω}{dt} + D ω = T - {T}_{gen}\end{matrix} ,$$

where p represents a number of poles in the synchronous motor, λ_{q} represents the q-component of the stator magnetic flux linkage, λ_{d} represents the d-component of the stator magnetic flux linkage,

$${i}_{s 2}^{d}$$

represents the second d-component,

$${i}_{s 2}^{q}$$

represents the second q-component, J represents rotational inertia of the synchronous motor, D represents a coefficient of viscosity and air-damping of the synchronous motor in air, T represents a mechanical torque of the synchronous motor, ω represents the second rotor angular velocity, θ represents the second rotor angle, and t represents time in simulation.

In an embodiment, the step S2 comprises: obtaining a stator-rotor voltage equation of the synchronous motor, and discretizing the stator-rotor voltage equation through an implicit trapezoidal rule to obtain a first transformation equation; performing Park transformation on the first transformation equation, eliminating a rotor variable in the first transformation equation, and using average resistance for a direct-axis and a quadrature-axis, to obtain a Thevenin equation for a stator; transforming the Thevenin equation for the stator to the first equation of Norton equivalent circuit; and transforming the first equation of Norton equivalent circuit expressed in the dq0 reference frame into the second equation of Norton equivalent circuit expressed in the abc reference frame through phasor coordinate transformation.

The first equation of Norton equivalent circuit is as follows.

$${i}_{d , source} = \frac{{e}_{d , mod}}{{R}_{ave}} ; {i}_{q , source} = \frac{{e}_{q , mod}}{{R}_{ave}} ; {i}_{0 , source} = \frac{{e}_{0}}{{R}_{0}}$$

$${R}_{ave} = ( {R}_{d} + {R}_{q} ) / 2 ; {e}_{d , mod} = {e}_{d} - \frac{{R}_{d} - {R}_{q}}{2} {i}_{s 1}^{d} ; {e}_{q , mod} = {e}_{q} - \frac{{R}_{d} - {R}_{q}}{2} {i}_{s 1}^{q}$$

The phasor coordinate transformation formula is as follows.

$$[ \begin{matrix}{i}_{a , source} \\ {i}_{b , source} \\ {i}_{c , source}\end{matrix} ] = \frac{\sqrt{2}}{\sqrt{3}} [ \begin{matrix}cos {θ}_{1} & sin {θ}_{1} & \frac{1}{\sqrt{2}} \\ cos ( {θ}_{1} - 120 ° ) & sin ( {θ}_{1} - 120 ° ) & \frac{1}{\sqrt{2}} \\ cos ( {θ}_{1} + 120 ° ) & sin ( {θ}_{1} + 120 ° ) & \frac{1}{\sqrt{2}}\end{matrix} ] [ \begin{matrix}{i}_{d , source} \\ {i}_{q , source} \\ {i}_{0 , source}\end{matrix} ]$$

$${i}_{s 1}^{d}$$

represents the first d-component of the armature current,

$${i}_{s 1}^{q}$$

represents the first q-component of the armature current, R_{d}, R_{q} and R₀ are resistance parameters in a resistance matrix in the Thevenin equation, e_{d}, e_{q} and e₀ are voltage parameters in a voltage-source matrix in the Thevenin equation, i_{d, source} represents a first current of a direct-axis in first equation of Norton equivalent circuit, i_{q, source} represents a second current of a quadrature-axis in the first equation of Norton equivalent circuit, i_{0, source} represents a third current of a zero component in the first equation of Norton equivalent circuit, θ₁ represents a first rotor angle, i_{a, source} represents a first current of an a-phase current source in the second equation of Norton equivalent circuit, i_{b, source} represents a second current of a b-phase current source in the second equation of Norton equivalent circuit, and i_{c, source} represents a third current of a c-phase current source in a second equation of Norton equivalent circuit.

In an embodiment, the step S4 comprises: performing Park transformation on the three phase-voltages to obtain voltage components of a direct-axis, a quadrature-axis, and a zero sequence; calculating the second q-component of the armature current and the second d-component of the armature current according to matrix parameters of a Thevenin equation for a stator and the voltage components through an armature-current calculation equation; calculating the rotor current according to parameters of the synchronous motor, the voltage components, the second q-component of the armature current, and the second d-component of the armature current through a rotor-current calculation equation; calculating the d-component and the q-component of the stator magnetic flux linkage according to the parameters of the synchronous motor, the second q-component of the armature current, the second d-component of the armature current, the first d-component of magnetic flux linkage at the knee point, and the first q-component of magnetic flux linkage at the knee point, through a stator-flux-linkage-component calculation equation.

The Park transformation is implemented through a following equation.

$$[ \begin{matrix}{v}_{d} \\ {v}_{q} \\ {v}_{0}\end{matrix} ] = \frac{\sqrt{2}}{\sqrt{3}} [ \begin{matrix}cos {θ}_{1} & cos ( {θ}_{1} - 120 ° ) & cos ( {θ}_{1} + 120 ° ) \\ sin {θ}_{1} & sin ( {θ}_{1} - 120 ° ) & sin ( {θ}_{1} + 120 ° ) \\ \frac{1}{\sqrt{2}} & \frac{1}{\sqrt{2}} & \frac{1}{\sqrt{2}}\end{matrix} ] [ \begin{matrix}{v}_{a} \\ {v}_{b} \\ {v}_{c}\end{matrix} ]$$

The armature-current calculation equation is as follows.

$${i}_{s 2}^{d} = ( {e}_{d , mod} - {v}_{d} ) / {R}_{ave} ; {i}_{s 2}^{q} = ( {e}_{q , mod} - {v}_{q} ) / {R}_{ave} ; {i}_{s 2}^{0} = ( {e}_{0} - {v}_{0} ) / {R}_{0}$$

$${R}_{ave} = ( {R}_{d} + {R}_{q} ) / 2 ; {e}_{d , mod} = {e}_{d} - \frac{{R}_{d} - {R}_{q}}{2} {i}_{s 1}^{d} ; {e}_{q , mod} = {e}_{q} - \frac{{R}_{d} - {R}_{q}}{2} {i}_{s 1}^{q}$$

The rotor-current calculation equation is as follows.

$$\begin{matrix}{i}_{r} = {R}_{sr}^{dq {0}^{- 1}} ( {P}^{- 1} {h}_{s}^{PD} - {v}_{s}^{dq 0} - {R}_{ss}^{dq 0} {i}_{s}^{dq 0} ) ; \\ {i}_{r} = {[ \begin{matrix}{i}_{f} & {i}_{D} & {i}_{g} & {i}_{Q}\end{matrix} ]}^{T} \\ {v}_{s}^{dq 0} = {[ \begin{matrix}{v}_{d} & {v}_{q} & {v}_{0}\end{matrix} ]}^{T} \\ {i}_{s}^{dq 0} = {[ \begin{matrix}{i}_{s 2}^{d} & {i}_{s 2}^{q} & {i}_{0}\end{matrix} ]}^{T}\end{matrix}$$

$${h}_{s}^{PD} = - {R}_{s} {\hat{i}}_{s} + k {\hat{λ}}_{s} - {\hat{v}}_{s}$$

$$P = \frac{\sqrt{2}}{\sqrt{3}} [ \begin{matrix}cos {θ}_{1} & cos ( {θ}_{1} - 120 ° ) & cos ( {θ}_{1} + 120 ° ) \\ sin {θ}_{1} & sin ( {θ}_{1} - 120 ° ) & sin ( {θ}_{1} + 120 ° ) \\ \frac{1}{\sqrt{2}} & \frac{1}{\sqrt{2}} & \frac{1}{\sqrt{2}}\end{matrix} ]$$

$${R}_{ss}^{dq 0} = {R}_{s} + {kL}_{ss}^{dq 0} ; {R}_{sr}^{dq 0} = {kL}_{sr}^{dq 0}$$

The stator-flux-linkage-component calculation equation is as follows.

$${λ}_{d} = {λ}_{ld} + {λ}_{md} ; {λ}_{q} = {λ}_{lq} + {λ}_{mq} ; {λ}_{m} = \sqrt{{λ}_{md}^{2} + {λ}_{mq}^{2}}$$

$${λ}_{ld} = {L}_{ld} {i}_{s 2}^{d} ; {λ}_{md} = {bL}_{md , u} {i}_{s 2}^{d} + \frac{\sqrt{2}}{\sqrt{3}} {bL}_{md , u} {i}_{f} + \frac{\sqrt{2}}{\sqrt{3}} {bL}_{md , u} {i}_{D} + {λ}_{knee 1 , d}$$

$${λ}_{lq} = {L}_{lq} {i}_{s 2}^{q} ; {λ}_{mq} = {bL}_{mq , u} {i}_{s 2}^{q} + \frac{\sqrt{2}}{\sqrt{3}} {bL}_{mq , u} {i}_{g} + \frac{\sqrt{2}}{\sqrt{3}} {bL}_{mq , u} {i}_{Q} + {λ}_{knee 1 , q}$$

$${i}_{s 2}^{d}$$

represents the second d-component,

$${i}_{s 2}^{q}$$

represents the second q-component of a second current, R_{d}, R_{q} and R₀ are resistance parameters in a resistance matrix in the Thevenin equation, e_{d}, eq and e₀ are voltage parameters in a voltage-source matrix in the Thevenin equation for the stator, θ₁ represents the first rotor angle, vₐ represents a voltage of an a-phase in the three phase-voltages, v_{b} represents a voltage of a b-phase in the three phase-voltages, v_{c} represents a voltage of a c-phase in the three phase-voltages, v_{d} represents a first voltage on the d-axis among the voltage components, v_{q} represents a second voltage on the q-axis among the voltage components, v₀ represents a third voltage on the zero sequence among the voltage components, λ_{d} represents the d-component of the stator magnetic flux linkage, λ_{q} represents the q-component of the stator magnetic flux linkage, λₘ represents the magnetic flux linkage of the air gap, λ_{md} represents the d-component of the air-gap magnetic flux linkage, λ_{mq} represents the q-component of the air-gap magnetic flux linkage, λ_{lq} represents a q-component of a leakage magnetic flux linkage, λ_{ld} represents a d-component of the leakage magnetic flux linkage, L_{md,u} represents a direct-axis mutual inductance under the unsaturation state, L_{ld} represents a direct-axis leakage magnetic flux linkage, L_{mq,u} represents a quadrature-axis mutual inductance under the unsaturation state, L_{lq} represents a quadrature-axis leakage magnetic flux linkage, L_{kneel,d} represents the first d-component of magnetic flux linkage at the knee point, and L_{kneel,q} represents the first q-component of magnetic flux linkage at the knee point. The parameters of the synchronous motor comprises: a saturation parameter of the synchronous motor b, a field current i_{f}, a current i_{D} of a direct-axis damping winding D, a current i_{g} of a quadrature-axis damping winding g, and a current i_{Q} of another quadrature-axis damping winding Q. iᵣ represents a rotor current matrix,

$${L}_{ss}^{dq 0}$$

represents a stator self-inductance matrix of the synchronous motor under the dq0 reference frame, Rₛ represents a stator resistance matrix of the synchronous motor, k is equal to 2/Δt,

$${L}_{sr}^{dq 0}$$

represents a stator-rotor mutual-inductance matrix of the synchronous motor under the dq0 reference frame, îₛ represents a stator current matrix obtained in a immediately previous time step, [symbol] represents a stator voltage matrix obtained in the immediately previous time step, and [symbol] represents a phase domain matrix of a stator magnetic flux linkage obtained in the immediately previous time step.

In an embodiment, the step S3 comprises: calculating the inverse of the equivalent

resistance matrix in the second equation of Norton equivalent circuit to obtain the equivalent conductance matrix; inputting, before the next time step, the obtained equivalent conductance matrix into the network conductance matrix; and solving the network conductance matrix through a network solving equation to obtain the three phase-voltages. The network solving equation is YV=1, where Y represents the network conductance matrix, I represents a current matrix comprising current parameters in the second equation of Norton equivalent circuit, and V represents a voltage matrix comprising the three phase-voltages.

A system for modeling electromagnetic transients of a synchronous motor based on magnetic saturation is provided according to an embodiment of the present disclosure. The system comprises: a predicting module, configured to predict a first rotor angular velocity, a first rotor angle, a first quadrature-axis component (q-component) of an armature current, a direct-axis component (d-component) of the armature current, a first d-component of magnetic flux linkage at a knee point of a magnetic-flux-linkage curve, and a first q-component of magnetic flux linkage at the knee point, of the synchronous motor at a given moment through linear extrapolation, and obtain magnetic flux linkage at the knee point indicating transition between an unsaturated state and a saturated state of the synchronous motor; a first processing module, configured to determine a first equation of Norton equivalent circuit for simulating the synchronous motor according to the first q-component of the armature current and the first current d-component of the armature current, and transform the first equation of Norton equivalent circuit expressed in a direct-quadrature-zero (dq0) reference frame into a second equation of Norton equivalent circuit expressed in a three-phase (abc) reference frame through coordinate transformation; a first calculating module, configured to determine an equivalent conductance matrix, which is an inverse of an equivalent resistance matrix in the second equation of Norton equivalent circuit, and solve a network conductance matrix, through substituting the determined equivalent conductance matrix into the network conductance matrix, to obtain three phase-voltages at ports of the synchronous motor; a second processing module, configured to determine, according to the three phase-voltages, a second q-component and a second d-component of the armature current of the synchronous motor and a rotor current of the synchronous motor, and determine a d-component of a stator magnetic flux linkage, a q-component of the stator magnetic flux linkage, and magnetic flux linkage of an air gap, of the synchronous motor according to the second q-component of the armature current, the second d-component of the armature current, the first d-component of magnetic flux linkage at the knee point, and the first q-component of magnetic flux linkage at the knee point; a second calculating module, configured to, in response to the magnetic flux linkage of the air gap being less than or equal to an air-gap magnetic-flux-linkage threshold, solve a mechanical system equation, through substituting the second q-component of the armature current, the second d-component of the armature current, the d-component of the stator magnetic flux linkage, and the q-component of the stator magnetic flux linkage into the mechanical system equation, to obtain a second rotor angular velocity and a second rotor angle of the synchronous motor, and determine a second d-component and a second q-component of magnetic flux linkage at the knee point of the synchronous motor according to the d-component of the stator magnetic flux linkage, the q-component of the stator magnetic flux linkage, and the magnetic flux linkage at the knee point; a determining module, configured to determine absolute differences between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively, and output the second rotor angular velocity and the second rotor angle in response to each of the absolute differences being smaller than a respective difference threshold of said absolute difference.

A device is further provided according to an embodiment of the present disclosure. The device comprises a processor and a memory, where the memory is configured to store program codes and transmit the program codes to the processor, and the processor is configured to execute instructions in the program codes to perform the foregoing method according to any foregoing embodiment.

The foregoing technical solutions according to embodiments of the present disclosure have following advantages. The method and the system for modeling electromagnetic transients of the synchronous motor based on magnetic saturation, and the device, are provided according to embodiments of the present disclosure. The method comprises following steps. In step S1, the first rotor angular velocity, the first rotor angle, the first quadrature-axis component (q-component) of an armature current, the direct-axis component (d-component) of the armature current, the first d-component of magnetic flux linkage at the knee point of the magnetic-flux-linkage curve, and the first q-component of magnetic flux linkage at the knee point, of the synchronous motor at the given moment is predicted through linear extrapolation. The magnetic flux linkage at the knee point indicating transition between an unsaturated state and a saturated state of the synchronous motor is obtained. In step S2, a first current of the direct-axis, a second current of the quadrature-axis, and a third current of the zero sequence, of current sources in parallel with respective resistors, are determined according to the first q-component of the armature current and the first current d- component of the armature current, and the first current of the direct-axis, the second current of the quadrature-axis, and the third current of the zero sequence are subject to phasor transformation to obtain a first current of a first phase, a second current of a second phase, and a third current of a third phase. In step S3, the first phase, the second current of the second phase, and the third current of the third phase are inputted into the network conductance matrix, and the network conductance matrix is then solved to obtain voltages of the first phase, the second phase and the third phase. In step S4, the second q-component and the second d-component of the armature current of the synchronous motor and the rotor current of the synchronous motor are determined according to the voltages of the first phase, the second phase and the third phase. The d-component of the stator magnetic flux linkage, the q-component of the stator magnetic flux linkage, and the magnetic flux linkage of the air gap are determined to the second q-component of the armature current, the second d-component of the armature current, the first d-component of magnetic flux linkage at the knee point, and the first q-component of magnetic flux linkage at the knee point. In step S5, in response to the magnetic flux linkage of the air gap being less than or equal to the air-gap magnetic-flux-linkage threshold, the mechanical system equation is solved, through substituting the second q-component of the armature current, the second d-component of the armature current, the d-component of the stator magnetic flux linkage, and the q-component of the stator magnetic flux linkage into the mechanical system equation, to obtain the second rotor angular velocity and the second rotor angle of the synchronous motor. The second d-component and the second q-component of magnetic flux linkage at the knee point of the synchronous motor are determined according to the d-component of the stator magnetic flux linkage, the q-component of the stator magnetic flux linkage, and the magnetic flux linkage at the knee point. In step S6, the absolute differences are determined between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively. The process returns to step S1 for the next time step in response to each of the absolute differences being smaller than the respective difference threshold of said absolute difference. In the foregoing method, the first rotor angular velocity, the first rotor angle, the first q-component of the armature current, and the first d-component of the armature current, the first d-component of magnetic flux linkage at the knee point, and the first q-component of magnetic flux linkage at the knee point, are predicted for the synchronous motor and then analyzed to obtain corresponding quantities, i.e., the second q-component, the second d-component, the second rotor angular velocity, the second rotor angle, the second d-component of magnetic flux linkage at the knee point, and the second q-component of magnetic flux linkage at the knee point. Historical values and current values of rotational electromotive force of the synchronous motor are not calculated, which improves accuracy of the simulation. Moreover, a result of the calculation can reach accuracy of phase-domain models while maintaining computational efficiency of dq0 models. That is, the method provided herein has high simulation accuracy and fast calculation efficiency and is applicable to development of simulation software for electromagnetic transient of power systems in practical engineering. Addressed is a technical issue that modeling rotating motors under magnetic saturation in conventional software for electromagnetic transient simulation has low accuracy and low efficiency.

Hereinabove provide are merely brief description of technical solutions of the present disclosure. Hereinafter detailed embodiments of the present disclosure are provided, such that technical means of the present disclosure are clarified and enabled according to content of the embodiments, and objectives, features, and advantages of embodiments of the present disclosure would become more intelligible.

### BRIEF DESCRIPTION OF THE DRAWINGS

Additional advantages and benefits would become clear to those skilled in the art on a basis of detailed description of preferable embodiments as follows. The drawings are only intended for illustrating the preferable embodiments, not limiting the present disclosure. In the drawings, same reference symbols represent identical components.

FIG. 1 is a flow chart of a method for modeling electromagnetic transients of a synchronous motor based on magnetic saturation according to an embodiment of the present disclosure.

FIG. 2 is a line graph of magnetic flux linkage of an unsaturation state and a saturation state of a synchronous motor according to an embodiment of the present disclosure.

FIG. 3 is a schematic box diagram of a system for modeling electromagnetic transients of a synchronous motor based on magnetic saturation according to an embodiment of the present disclosure.

### DETAILED DESCRIPTION OF THE EMBODIMENTS

Hereinafter technical solutions in embodiments of the present disclosure are described clearly and completely in conjunction with the drawings in embodiments of the present closure to improve clarity and intelligibility of objectives, features, and advantages of embodiments of the present disclosure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

A method and a system for modeling electromagnetic transients of a synchronous motor based on magnetic saturation, and a device, are provided according to embodiments of the present disclosure. Addressed is a technical issue that modeling rotating motors under magnetic saturation in conventional software for electromagnetic transient simulation has low accuracy and low efficiency.

### First Embodiment

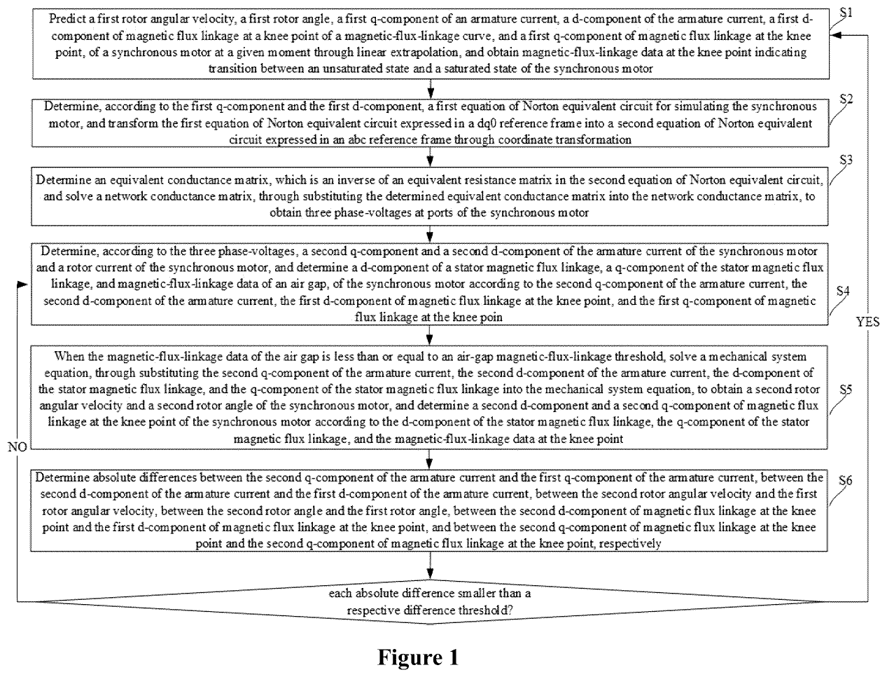

FIG. 1 is a flow chart of a method for modeling electromagnetic transients of a synchronous motor based on magnetic saturation according to an embodiment of the present disclosure. Here a generator is taken as an example of the synchronous motor.

Reference is made to FIG. 1. In an embodiment, a method for modeling electromagnetic transients of a synchronous motor based on magnetic saturation provided according to the embodiment of the present disclosure includes the following steps from step S1 to step S6.

In step S1, a first rotor angular velocity, a first rotor angle, a first quadrature-axis component (q-component) of an armature current, a direct-axis component (d-component) of the armature current, a first d-component of magnetic flux linkage at a knee point of a magnetic-flux-linkage curve, and a first q-component of magnetic flux linkage at the knee point, of the synchronous motor at a given moment are predicted through linear extrapolation. Magnetic flux linkage at the knee point indicating transition between an unsaturated state and a saturated state of the synchronous motor is obtained.

In an embodiment, the first rotor angular velocity of the synchronous motor is predicted through linear extrapolation as follow: ω₁(t)=2ω₁(t−Δt)−ω₁(t−2Δt). t represents time in simulation of the synchronous motor, specifically the given moment. Δt represents a step size in the simulation. Then, the first rotor angle may be obtained through performing trapezoidal integration on the first rotor angular velocity.

An equation of the trapezoidal integration may be as follows:

$${θ}_{1} ( t ) = {θ}_{1} ( t - Δ t ) - \frac{Δ t}{2} \{ {ω}_{1} ( t - Δ t ) + {ω}_{1} ( t ) \} .$$

Here the linear extrapolation method may be further adopted for predicting the first q-component and the first d-component of the armature current at the given moment.

An equation for predicting the first d-component of the armature current at the given moment through the linear extrapolation may be as follows:

$${i}_{s 1}^{d} ( t ) = 2 {i}_{s 1}^{d} ( t - Δ t ) - {i}_{s 1}^{d} ( t - 2 Δ t ) .$$

An equation for predicting the first q-component of the armature current at the given moment through the linear extrapolation may be as follows:

$${i}_{s 1}^{q} ( t ) = 2 {i}_{s 1}^{q} ( t - Δ t ) - {i}_{s 1}^{q} ( t - 2 Δ t ) .$$

Here the linear extrapolation method may be further adopted for predicting the first q-component and the first d-component of magnetic flux linkage at the knee point of the magnetic-flux-linkage curve at the given moment. The magnetic flux linkage λₖₙₑₑ at the knee point between the unsaturated state and the saturated state of the synchronous motor at the given moment is further obtained.

Equations for predicting the first d-component λ_{kneel, d} and the first q-component λ_{kneel, q} of magnetic flux linkage at the knee point at the given moment through the linear extrapolation may be as follows.

$$\begin{matrix}{λ}_{knee 1 , d} ( t ) = 2 {λ}_{knee 1 , d} ( t - Δ t ) - {λ}_{knee 1 , d} ( t - 2 Δ t ) \\ {λ}_{knee 1 , q} ( t ) = 2 {λ}_{knee 1 , q} ( t - Δ t ) - {λ}_{knee 1 , q} ( t - 2 Δ t )\end{matrix}$$

In step S2, a first equation of Norton equivalent circuit for simulating the synchronous motor is determined according to the first q-component and the first d-component, and the first equation of Norton equivalent circuit expressed in a direct-quadrature-zero (dq0) reference frame is transformed into a second equation of Norton equivalent circuit expressed in a three-phase (abc) reference frame through coordinate transformation. That is, the first q-component and the first d-component are processed to obtain a first current on a direct-axis, a second current on a quadrature-axis, and a third current of a zero sequence, which present in the first equation of Norton equivalent circuit. The first current, the second current, and the third current are subject coordinate transformation to obtain a first current, a second current, and a third current of phases a, b, and c, respectively, which present in the second equation of Norton equivalent circuit.

This step may process the first rotor angular velocity and the first rotor angle, which are predicted in step S1, to construct the first equation of Norton equivalent circuit, which is an equivalence of the synchronous motor. Thereby, the first current on the direct-axis, the second current on the quadrature-axis, and the third current of the zero sequence, in the first equation of Norton equivalent circuit are obtained for the synchronous motor simplified as a resistor and a current source that are connected parallel. Then, the first current on the direct-axis, the second current on the quadrature-axis, and the third current of the zero sequence are transformed from the dq0 reference frame into the first current, the second current, and the third current of the second equation of Norton equivalent circuit under the abc reference frame.

In step S3, an equivalent conductance matrix, which is an inverse of an equivalent resistance matrix in the second equation of Norton equivalent circuit is determined, and a network conductance matrix is solved, through substituting the determined equivalent conductance matrix into the network conductance matrix, to obtain three phase-voltages at ports of the synchronous motor. That is, the first current, the second current, and the third current of phases a, b, and c are substituted into the network conductance matrix to obtain the three phase-voltages to the first current, the second current and the third current, respectively. The three phase-voltages are called an a-phase voltage, a b-phase voltage, and a c-phase voltage.

Solving the network conductance matrix through substituting the determined equivalent conductance matrix into the network conductance matrix comprises following steps. Before the next time step, the inverse of the equivalent resistance matrix in the second equation of Norton equivalent circuit is calculated to obtain the equivalent conductance matrix. Then, the obtained equivalent conductance matrix is inputted into the network conductance matrix, and the network conductance matrix is solved through a network solving equation to obtain the three phase-voltages. The network solving equation is YV=1. Y represents the network conductance matrix. I represents history current source(s) of the whole network and comprises a current matrix comprising current parameters in the second equation of Norton equivalent circuit. V represents three-phase voltages of to-be-solved nodes in the entire network and comprises a voltage matrix comprising the three phase-voltages.

In step S4, a second q-component and a second d-component of the armature current of the synchronous motor, and a rotor current of the synchronous motor, are determined according to the three phase-voltages. A d-component of a stator magnetic flux linkage, a q-component of the stator magnetic flux linkage, and magnetic flux linkage of an air gap, of the synchronous motor are determined according to the second q-component of the armature current, the second d-component of the armature current, the first d-component of magnetic flux linkage at the knee point, and the first q-component of magnetic flux linkage at the knee point.

The second q-component of the armature current, the second d-component of the armature current, and the rotor current are calculated through performing Park transformation on the a-phase voltage, the b-phase voltage, and the c-phase voltage. The d-component of the stator magnetic flux linkage, the q-component of the stator magnetic flux linkage, and magnetic flux linkage of an air gap are determined according to the second q-component of the armature current, the second d-component of the armature current, the first d-component of magnetic flux linkage at the knee point, the first q-component of magnetic flux linkage at the knee point, and parameters in an inductance matrix of the synchronous motor.

In step S5, in a case that the magnetic flux linkage of the air gap is less than or equal to an air-gap magnetic-flux-linkage threshold, a mechanical system equation is solved, through substituting the second q-component of the armature current, the second d-component of the armature current, the d-component of the stator magnetic flux linkage, and the q-component of the stator magnetic flux linkage into the mechanical system equation, to obtain a second rotor angular velocity and a second rotor angle of the synchronous motor. In such case, a second d-component and a second q-component of magnetic flux linkage at the knee point of the synchronous motor are further determined according to the d-component of the stator magnetic flux linkage, the q-component of the stator magnetic flux linkage, and the magnetic flux linkage at the knee point.

This step mainly inputs the second q-component of the armature current, the second d-component of the armature current, the d-component of the stator magnetic flux linkage, and the q-component of the stator magnetic flux linkage into the mechanical system equation to obtain the second rotor angular velocity and the second rotor angle. The second d-component and the second q-component of magnetic flux linkage at the knee point of the synchronous motor are further determined according to the d-component of the stator magnetic flux linkage, the q-component of the stator magnetic flux linkage, and the magnetic flux linkage at the knee point, and hence they are provided for processing in following step S6. The air-gap magnetic-flux-linkage threshold may be configured on requirement and is not limited in detail herein.

In an embodiment, the mechanical system equation is as follows.

$$\begin{matrix}{T}_{gen} = \frac{p}{2} ( {λ}_{d} {i}_{s 2}^{q} - {λ}_{q} {i}_{s 2}^{d} ) \\ ω = \frac{d θ}{dt} \\ J \frac{d ω}{dt} = D ω = T - {T}_{gen}\end{matrix}$$

p represents a number of poles in the synchronous motor. λ_{q} represents the q-component of the stator magnetic flux linkage, and λ_{d} represents the d-component of the stator magnetic flux linkage.

$${i}_{s 2}^{d}$$

represents the second u-component, and

$${i}_{s 2}^{q}$$

represents the second q-component. J represents rotational inertia of the synchronous motor. D represents a coefficient of viscosity and air-damping of the synchronous motor in air. T represents a mechanical torque of the synchronous motor. ω represents the second rotor angular velocity. θ represents the second rotor angle. t represents the time in simulation. T may be equal to a ratio of mechanical power P₀ of the synchronous motor to an initial angular velocity ωₛ of the synchronous motor, that is, T=P₀/ωₛ.

In step S6, absolute differences are determined between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively. The process returning to step S1 for a next time step in a case that each of the absolute differences is smaller than a respective difference threshold of such absolute difference.

This step mainly calculates differences between the second q-component, the second d-component, the second rotor angular velocity, the second rotor angle, the second d-component of magnetic flux linkage at the knee point, and the second q-component of magnetic flux linkage at the knee point, which are obtained in steps S4 and S5, and the first q-component, the first d-component, the first rotor angular velocity, the first rotor angle, the first d-component of magnetic flux linkage at the knee point, and the first q-component of magnetic flux linkage at the knee point, which are predicted in step S1, respectively. Absolute values of the differences are obtained, and then it is determined whether all the absolute values are less than respective error thresholds. In a case that all the absolute values of the differences are less than their respective error thresholds, the process returns to the step S1 and performs modeling on next electromagnetic transient of the synchronous motor. In a case that any of the absolute values is not less than its respective error threshold, the process returns to the step S4 and re-calculates the second q-component, the second d-component, the second rotor angular velocity, the second rotor angle, the second d-component of magnetic flux linkage at the knee point, and the second q-component of magnetic flux linkage at the knee point.

The method for modeling electromagnetic transients of the synchronous motor based on magnetic saturation is provided according to embodiments of the present disclosure. The method comprises following steps. In step S1, the first rotor angular velocity, the first rotor angle, the first quadrature-axis component (q-component) of an armature current, the direct-axis component (d-component) of the armature current, the first d-component of magnetic flux linkage at the knee point of the magnetic-flux-linkage curve, and the first q-component of magnetic flux linkage at the knee point, of the synchronous motor at the given moment is predicted through linear extrapolation. The magnetic flux linkage at the knee point indicating transition between an unsaturated state and a saturated state of the synchronous motor is obtained. In step S2, a first current of the direct-axis, a second current of the quadrature-axis, and a third current of the zero sequence, of current sources in parallel with respective resistors, are determined according to the first q-component of the armature current and the first current d-component of the armature current, and the first current of the direct-axis, the second current of the quadrature-axis, and the third current of the zero sequence are subject to phasor transformation to obtain a first current of a first phase, a second current of a second phase, and a third current of a third phase. In step S3, the first phase, the second current of the second phase, and the third current of the third phase are inputted into the network conductance matrix, and the network conductance matrix is then solved to obtain voltages of the first phase, the second phase and the third phase. In step S4, the second q-component and the second d-component of the armature current of the synchronous motor and the rotor current of the synchronous motor are determined according to the voltages of the first phase, the second phase and the third phase. The d-component of the stator magnetic flux linkage, the q-component of the stator magnetic flux linkage, and the magnetic flux linkage of the air gap are determined to the second q-component of the armature current, the second d-component of the armature current, the first d-component of magnetic flux linkage at the knee point, and the first q-component of magnetic flux linkage at the knee point. In step S5, in response to the magnetic flux linkage of the air gap being less than or equal to the air-gap magnetic-flux-linkage threshold, the mechanical system equation is solved, through substituting the second q-component of the armature current, the second d-component of the armature current, the d-component of the stator magnetic flux linkage, and the q-component of the stator magnetic flux linkage into the mechanical system equation, to obtain the second rotor angular velocity and the second rotor angle of the synchronous motor. The second d-component and the second q-component of magnetic flux linkage at the knee point of the synchronous motor are determined according to the d-component of the stator magnetic flux linkage, the q-component of the stator magnetic flux linkage, and the magnetic flux linkage at the knee point. In step S6, the absolute differences are determined between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively. The process returns to step S1 for the next time step in response to each of the absolute differences being smaller than the respective difference threshold of said absolute difference. In the foregoing method, the first rotor angular velocity, the first rotor angle, the first q-component of the armature current, and the first d-component of the armature current, the first d-component of magnetic flux linkage at the knee point, and the first q-component of magnetic flux linkage at the knee point, are predicted for the synchronous motor and then analyzed to obtain corresponding quantities, i.e., the second q-component, the second d-component, the second rotor angular velocity, the second rotor angle, the second d-component of magnetic flux linkage at the knee point, and the second q-component of magnetic flux linkage at the knee point. Historical values and current values of rotational electromotive force of the synchronous motor are not calculated, which improves accuracy of the simulation. Moreover, a result of the calculation can reach accuracy of phase-domain models while maintaining computational efficiency of dq0 models. That is, the method provided herein has high simulation accuracy and fast calculation efficiency and is applicable to development of simulation software for electromagnetic transient of power systems in practical engineering. Addressed is a technical issue that modeling rotating motors under magnetic saturation in conventional software for electromagnetic transient simulation has low accuracy and low efficiency.

In an embodiment, step S2 comprises following sub-steps.

A stator-rotor voltage equation of the synchronous motor is obtained, and the stator-rotor voltage equation is discretized through an implicit trapezoidal rule to obtain a first transformation equation.

Park transformation is performed on the first transformation equation, a rotor variable in the first transformation equation is eliminated, and average resistance for a direct-axis and a quadrature-axis is utilized, to obtain a Thevenin equation for a stator.

The Thevenin equation for the stator is mathematically transformed to the first equation of Norton equivalent circuit.

The first equation of Norton equivalent circuit expressed in the dq0 reference frame is transformed into the second equation of Norton equivalent circuit expressed in the abc reference frame through phasor coordinate transformation.

In an embodiment, the first equation of Norton equivalent circuit is as follows.

$$\begin{matrix}{i}_{d , source} = \frac{{e}_{d , mod}}{{R}_{ave}} ; {i}_{q , source} = \frac{{e}_{q , mod}}{{R}_{ave}} ; {i}_{0 , source} = \frac{{e}_{0}}{{R}_{0}} \\ {R}_{ave} = ( {R}_{d} + {R}_{q} ) / 2 ; {e}_{d , mod} = {e}_{d} - \frac{{R}_{d} - {R}_{q}}{2} {i}_{s 1}^{d} ; {e}_{q , mod} = {e}_{q} - \frac{{R}_{d} - {R}_{q}}{2} {i}_{s 1}^{q}\end{matrix}$$

The phasor coordinate transformation formula is as follows.

$$[ \begin{matrix}{i}_{a , source} \\ {i}_{b , source} \\ {i}_{c , source}\end{matrix} ] = \frac{\sqrt{2}}{\sqrt{3}} [ \begin{matrix}cos {θ}_{1} & sin {θ}_{1} & \frac{1}{\sqrt{2}} \\ cos ( {θ}_{1} - 120 ° ) & sin ( {θ}_{1} - {120}^{°} ) & \frac{1}{\sqrt{2}} \\ cos ( {θ}_{1} + 120 ° ) & sin ( {θ}_{1} + 120 ° ) & \frac{1}{\sqrt{2}}\end{matrix} ] [ \begin{matrix}{i}_{d , source} \\ {i}_{q , source} \\ {i}_{0 , source}\end{matrix} ]$$

$${i}_{s 1}^{d}$$

represents are first d-component of the armature current, and

$${i}_{s 1}^{q}$$

represents the first q-component of the armature current. R_{d}, R_{q} and R₀ are resistance parameters in a resistance matrix in the Thevenin equation. e_{d}, e_{q} and e₀ are voltage parameters in a voltage-source matrix in the Thevenin equation. i_{d, source} represents the first current of the direct-axis, i_{q, source} represents the second current of the quadrature-axis, and i_{0, source} represents the third current of the zero component. θ₁ represents a first rotor angle. i_{a, source} represents the first current of the a-phase, i_{b, source} represents the second current of the b-phase, and i_{c, source} represents the third current of the c-phase.

In an embodiment, the stator-rotor voltage equation and a magnetic flux linkage equation of the synchronous motor are obtained, and the stator-rotor voltage equation is discretized through the implicit trapezoidal rule to obtain the first transformation equation. Then, Park transformation is performed on the first transformation equation, the rotor variable(s) in the first transformation equation is eliminated, and the average resistance for the direct-axis and the quadrature-axis is utilized to obtain the Thevenin equation for the stator.

The stator-rotor voltage equation is as follows.

$$[ \begin{matrix}{v}_{s}^{abc} \\ {v}_{r}\end{matrix} ] = [ \begin{matrix}{R}_{s} & 0 \\ 0 & {R}_{r}\end{matrix} ] - \frac{d}{dt} [ \begin{matrix}{λ}_{s}^{abc} \\ {λ}_{r}\end{matrix} ]$$

The magnetic flux linkage equation is as follows.

$$[ \begin{matrix}{λ}_{s}^{abc} \\ {λ}_{r}\end{matrix} ] = L ( {θ}_{1} ) [ \begin{matrix}{i}_{s}^{abc} \\ {i}_{r}\end{matrix} ] = [ \begin{matrix}{L}_{ss} & {L}_{sr} \\ {L}_{rs} & {L}_{rr}\end{matrix} ] [ \begin{matrix}{i}_{s}^{abc} \\ {i}_{r}\end{matrix} ]$$

The first transformation equation is follows.

$$\begin{matrix}[ \begin{matrix}{v}_{s}^{abc} \\ {v}_{r}\end{matrix} ] = - [ \begin{matrix}{R}_{s} + {kL}_{ss} & {kL}_{sr} \\ {kL}_{rs} & {R}_{r} + {kL}_{rr}\end{matrix} ] [ \begin{matrix}{i}_{s}^{abc} \\ {i}_{r}\end{matrix} ] + [ \begin{matrix}{h}_{s}^{PD} \\ {h}_{r}^{PD}\end{matrix} ] \\ {h}_{s}^{PD} = - {R}_{s} {\hat{i}}_{s} + k {\hat{λ}}_{s} - {\hat{v}}_{s} \\ {h}_{r}^{PD} = - {R}_{r} {\hat{i}}_{r} + k {\hat{λ}}_{r} - {\hat{v}}_{r}\end{matrix}$$

$$P = \frac{\sqrt{2}}{\sqrt{3}} [ \begin{matrix}cos {θ}_{1} & cos ( {θ}_{1} - 120 ° ) & cos ( {θ}_{1} + 120 ° ) \\ sin {θ}_{1} & sin ( {θ}_{1} - 120 ° ) & sin ( {θ}_{1} + 120 ° ) \\ \frac{1}{\sqrt{2}} & \frac{1}{\sqrt{2}} & \frac{1}{\sqrt{2}}\end{matrix} ]$$

The Thevenin equation for the stator is as follows.

$$\begin{matrix}{v}_{s}^{dq 0} = - {R}_{dq 0} {i}_{s}^{dq 0} + {e}_{dq 0} \\ {R}_{dq 0} = diag ( {R}_{d} , {R}_{q} , {R}_{0} ) = {R}_{ss}^{dq 0} - {R}_{sr}^{dq 0} {R}_{rr}^{- 1} {R}_{rs}^{dq 0} \\ {e}_{dq 0} = {[ {e}_{d} {e}_{q} {e}_{0} ]}^{T} = {R}_{sr}^{dq 0} {R}_{rr}^{- 1} ( {v}_{r} - {h}_{r}^{PD} ) + {P}^{- 1} {h}_{s}^{PD}\end{matrix}$$

$${v}_{s}^{abc}$$

represents a stator phase-domain voltage matrix in a phase-domain matrix of the synchronous motor,

$${i}_{s}^{abc}$$

represents a stator current phase-domain matrix in the phase-domain matrix of the synchronous motor, and

$${λ}_{s}^{abc}$$

represents a magnetic-flux-linkage phase-domain matrix in the phase-domain matrix of the synchronous motor. vᵣ represents a rotor voltage matrix a magnetic-flux-linkage matrix of the synchronous motor, iᵣ represents a rotor current matrix in the magnetic-flux-linkage matrix of the synchronous motor, and λᵣ represents a magnetic-flux-linkage matrix in the magnetic-flux-linkage matrix of the synchronous motor. Rₛ represents a stator resistance matrix of the synchronous motor, and Rᵣ represents a rotor resistance of the synchronous motor. L(θ₁) represents an inductance of the synchronous motor with respect to the first rotor angle. Lₛₛ represents a stator self-inductance in a self-inductance matrix of the synchronous motor, Lᵣᵣ represents a rotor self-inductance in the self-inductance matrix of the synchronous motor, Lₛᵣ represents a stator mutual-inductance in an inductance matrix of the synchronous motor, and Lᵣₛ represents a rotor mutual-inductance in the inductance matrix of the synchronous motor. k is equal to 2/Δt. A variable marked with \hat{ } represents a corresponding quantity in the immediately previous time step, that is, a corresponding history quantity. R_{dq0} represents a resistance matrix for resistors in the Thevenin equation for the stator, and e_{dq0} represents a voltage-source matrix for voltage sources in series connection with the resistors. [symbol] in

$${h}_{s}^{PD}$$

are obtained directly from history solution quantities of the network. îₛ and [symbol] are in obtained through performing Park transformation on corresponding history current variables and history magnetic-flux-linkage variables under the dq0 reference frame. A value at the last moment is also utilized for vᵣ.

In an embodiment, the Park transformation is performed on the first transformation equation to obtain the second transformation equation, and then the rotor variable(s) in the second transformation equation are eliminated to obtain the Thevenin equation.

The second transformation equation is follows.

$$\begin{matrix}[ \begin{matrix}{v}_{s}^{dq 0} \\ {v}_{r}\end{matrix} ] = - [ \begin{matrix}{R}_{ss}^{dq 0} & {R}_{sr}^{dq 0} \\ {R}_{rs}^{dq 0} & {R}_{rr}^{dq 0}\end{matrix} ] [ \begin{matrix}{i}_{s}^{dq 0} \\ {i}_{r}\end{matrix} ] + [ \begin{matrix}{P}^{- 1} {h}_{s}^{PD} \\ {h}_{r}^{PD}\end{matrix} ] \\ [ \begin{matrix}{R}_{ss}^{dq 0} & {R}_{sr}^{dq 0} \\ {R}_{rs}^{dq 0} & {R}_{rr}^{dq 0}\end{matrix} ] = [ \begin{matrix}{R}_{s} + {kL}_{ss}^{dq 0} & {kL}_{sr}^{dq 0} \\ {kL}_{rs}^{dq 0} & {R}_{r} + {kL}_{rr}^{dq 0}\end{matrix} ]\end{matrix}$$

[symbol] represents a stator voltage matrix of the synchronous motor under the dq0 reference frame, and [symbol] represents of a stator current matrix of the synchronous motor under the dq0 reference frame, [symbol] represents a stator self-inductance matrix of the synchronous motor under the dq0 reference frame, [symbol] represents a stator-rotor mutual-inductance matrix of the synchronous motor under the dq0 reference frame, and [symbol] represents a rotor-stator mutual-inductance matrix of the synchronous motor under the dq0 reference frame.

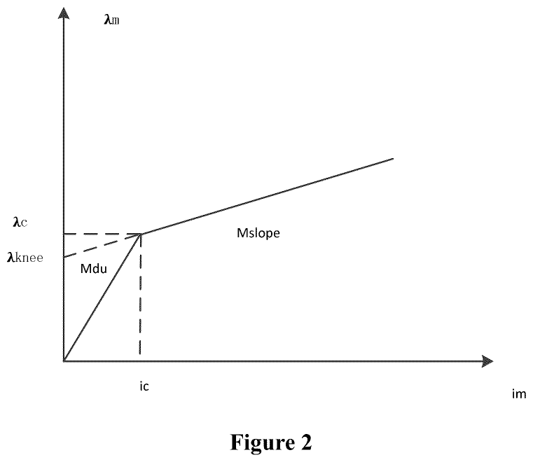

FIG. 2 is a line graph of magnetic flux linkage of an unsaturation state and a saturation state of a synchronous motor according to an embodiment of the present disclosure.

In an embodiment, the inductance matrix L^{dq0} of the synchronous motor is as follows.

$${L}^{dq 0} = [ \begin{matrix}{L}_{ss}^{dq 0} & {L}_{sr}^{dq 0} \\ {L}_{rs}^{dq 0} & {L}_{rr}\end{matrix} ] = [ \begin{matrix}{L}_{ld} + {bL}_{md , u} & 0 & 0 & {bL}_{md , u} & {bL}_{md , u} & 0 & 0 \\ 0 & {L}_{ld} + {bL}_{mq , u} & 0 & 0 & 0 & {bL}_{mq , u} & {bL}_{mq , u} \\ 0 & 0 & {L}_{0} & 0 & 0 & 0 & 0 \\ {bL}_{md , u} & 0 & 0 & {L}_{lf} + {bL}_{md , u} & {bL}_{md , u} & 0 & 0 \\ {bL}_{md , u} & 0 & 0 & {bL}_{md , u} & {L}_{lD} + {bL}_{md , u} & 0 & 0 \\ 0 & {bL}_{mq , u} & 0 & 0 & 0 & {L}_{lg} + {bL}_{mq , u} & {bL}_{mq , u} \\ 0 & {bL}_{mq , u} & 0 & 0 & 0 & {bL}_{mq , u} & {L}_{lQ} + {bL}_{mq , u}\end{matrix} ]$$

b represents a saturation parameter of a synchronous motor, L_{md,u} represents a direct-axis mutual inductance under the unsaturation state, L_{ld} represents a direct-axis leakage magnetic flux linkage, L_{mq,u} represents a quadrature-axis mutual inductance under the unsaturation state, L_{lq} represents a quadrature-axis leakage magnetic flux linkage, L_{lQ} represents a leakage inductance of a quadrature-axis damping winding Q of the synchronous motor, L_{lg} represents a leakage inductance of another quadrature-axis damping winding g of the synchronous motor, L_{if} represents a leakage inductance of a quadrature-axis field winding of a synchronous motor.

Reference is made to FIG. 2. b in the inductance matrix L^{dq0} of the synchronous motor is equal to Mₛₗₒₚₑ/M_{du} when the synchronous motor is in the saturation state, and b is equal to 1 when the synchronous motor is in the unsaturation state. The zero-load saturation curve of the synchronous motor is approximated by a line graph comprising two sloped segments. The slopes of the unsaturation state and the saturation state are denoted as M_{du} and Mₛₗₒₚₑ, respectively. Here the subscript “m” represents mutual inductance, the subscript “u” represents the unsaturation state, and subscripts “d”, “q”, and “0” represent the d-component, the q-component, and a component of the zero sequence in the dq0 reference frame.

The obtained Thevenin equation is under the dq0 reference frame. In an embodiment, the average resistance is utilized for the direct-axis and the quadrature-axis to obtain the modified Thevenin equation which is transformed to the stator side. Thereby, it is avoided to generate a time-varying and dissymmetrical resistance matrix that is three by three in size, and calculation accuracy is improved. The second equation of Norton equivalent circuit after the transformation is as follows.

$$[ \begin{matrix}{v}_{s}^{d} \\ {v}_{s}^{q} \\ {v}_{s}^{0}\end{matrix} ] = [ \begin{matrix}{e}_{d , m o d} \\ {e}_{q , m o d} \\ {e}_{0 , m o d}\end{matrix} ] - [ \begin{matrix}{R}_{ave} & & \\ & {R}_{ave} & \\ & & {R}_{0}\end{matrix} ] [ \begin{matrix}{i}_{s 1}^{d} \\ {i}_{s 1}^{q} \\ {i}_{s 1}^{0}\end{matrix} ] .$$

In an embodiment, step S4 comprises following sub steps.

Park transformation is performed on the three phase-voltages to obtain voltage components of a direct-axis, a quadrature-axis, and a zero sequence.

The second q-component of the armature current and the second d-component of the armature current are calculated according to matrix parameters of a Thevenin equation for a stator and the voltage components through an armature-current calculation equation.

The rotor current is calculated according to parameters of the synchronous motor, the voltage components, the second q-component of the armature current, and the second d-component of the armature current through a rotor-current calculation equation.

The d-component and the q-component of the stator magnetic flux linkage are calculated according to the parameters of the synchronous motor, the second q-component of the armature current, the second d-component of the armature current, the first d-component of magnetic flux linkage at the knee point, and the first q-component of magnetic flux linkage at the knee point, through a stator-flux-linkage-component calculation equation.

In an embodiment, the Park transformation is implemented through a following equation.

$$[ \begin{matrix}{v}_{d} \\ {v}_{q} \\ {v}_{0}\end{matrix} ] = \frac{\sqrt{2}}{\sqrt{3}} [ \begin{matrix}cos {θ}_{1} & cos ( {θ}_{1} - {120}^{∘} ) & cos ( {θ}_{1} + {120}^{∘} ) \\ sin {θ}_{1} & sin ( {θ}_{1} - {120}^{∘} ) & sin ( {θ}_{1} + {120}^{∘} ) \\ \frac{1}{\sqrt{2}} & \frac{1}{\sqrt{2}} & \frac{1}{\sqrt{2}}\end{matrix} ] [ \begin{matrix}{v}_{a} \\ {v}_{b} \\ {v}_{c}\end{matrix} ]$$

The armature-current calculation equation is as follows.

$${i}_{s 2}^{d} = ( {e}_{d , m o d} - {v}_{d} ) / {R}_{a v e} ; {i}_{s 2}^{q} = ( {e}_{q , m o d} - {v}_{q} ) / {R}_{a v e} ; {i}_{s 2}^{0} = ( {e}_{0} - {v}_{0} ) / {R}_{0}$$

$${R}_{a v e} = ( {R}_{d} + {R}_{q} ) / 2 ; {e}_{d , m o d} = {e}_{d} - \frac{{R}_{d} - {R}_{q}}{2} {i}_{s 1}^{d} ; {e}_{q , m o d} = {e}_{q} - \frac{{R}_{d} - {R}_{q}}{2} {i}_{s 1}^{q}$$

The rotor-current calculation equation is as follows.

$${i}_{r} = {R}_{s r}^{d q {0}^{- 1}} ( {P}^{- 1} {h}_{s}^{P D} - {v}_{s}^{d q 0} - {R}_{s s}^{d q 0} {i}_{s}^{d q 0} ) ;$$

$${i}_{r} = {[ \begin{matrix}{i}_{f} & {i}_{D} & {i}_{g} & {i}_{Q}\end{matrix} ]}^{T}$$

$${v}_{s}^{d q 0} = {[ \begin{matrix}{v}_{d} & {v}_{q} & {v}_{0}\end{matrix} ]}^{T}$$

$${i}_{s}^{d q 0} = {[ \begin{matrix}{i}_{s 2}^{d} & {i}_{s 2}^{q} & {i}_{0}\end{matrix} ]}^{T}$$

$${h}_{S}^{P D} = - {R}_{s} {î}_{s} + k {\hat{λ}}_{s} - {\hat{v}}_{s}$$

$$P = \frac{\sqrt{2}}{\sqrt{3}} [ \begin{matrix}cos {θ}_{1} & cos ( {θ}_{1} - {120}^{∘} ) & cos ( {θ}_{1} + {120}^{∘} ) \\ sin {θ}_{1} & sin ( {θ}_{1} - {120}^{∘} ) & sin ( {θ}_{1} + {120}^{∘} ) \\ \frac{1}{\sqrt{2}} & \frac{1}{\sqrt{2}} & \frac{1}{\sqrt{2}}\end{matrix} ]$$

$${R}_{ss}^{d q 0} = {R}_{s} + {kL}_{ss}^{d q 0} ; {R}_{sr}^{d q 0} = {kL}_{sr}^{d q 0}$$

The stator-flux-linkage-component calculation equation is as follows.

$${λ}_{d} = {λ}_{l d} + {λ}_{m d} ; {λ}_{q} = {λ}_{l q} + {λ}_{m q} ; {λ}_{m} = \sqrt{{λ}_{m d}^{2} + {λ}_{m q}^{2}}$$

$${λ}_{ld} = {L}_{ld} {i}_{s 2}^{d} ; {λ}_{m d} = b {L}_{md ,} {}_{u} {i}_{s 2}^{d} + \frac{\sqrt{2}}{\sqrt{3}} b {L}_{m d} , {}_{u} {i}_{f} + \frac{\sqrt{2}}{\sqrt{3}} {bL}_{m d} , {}_{u} {i}_{D} + {λ}_{kneel , d}$$

$${λ}_{lq} = {L}_{lq} {i}_{s 2}^{q} ; {λ}_{m d} = b {L}_{mq ,} {}_{u} {i}_{s 2}^{q} + \frac{\sqrt{2}}{\sqrt{3}} b {L}_{mq} , {}_{u} {i}_{g} + \frac{\sqrt{2}}{\sqrt{3}} {bL}_{mq} , {}_{u} {i}_{Q} + {λ}_{kneel , q}$$

$${i}_{s 2}^{d}$$

represents the second d-component, and

$${i}_{s 2}^{q}$$

represents the second q-component of a second current. R_{d}, R_{q} and R₀ are resistance parameters in a resistance matrix in the Thevenin equation. e_{d}, eq and e₀ are voltage parameters in a voltage-source matrix in the Thevenin equation for the stator. θ₁ represents the first rotor angle. vₐ represents a voltage of an a-phase in the three phase-voltages, v_{b} represents a voltage of a b-phase in the three phase-voltages, v_{c} represents a voltage of a c-phase in the three phase-voltages, v_{d} represents a first voltage on the d-axis among the voltage components, v_{q} represents a second voltage on the q-axis among the voltage components, v₀ represents a third voltage on the zero sequence among the voltage components. λ_{d} represents the d-component of the stator magnetic flux linkage, λ_{q} represents the q-component of the stator magnetic flux linkage, λₘ represents the magnetic flux linkage of the air gap, λ_{md} represents the d-component of the air-gap magnetic flux linkage, λ_{mq} represents the q-component of the air-gap magnetic flux linkage, λ_{lq} represents a q-component of a leakage magnetic flux linkage, λ_{ld} represents a d-component of the leakage magnetic flux linkage. L_{md,u} represents a direct-axis mutual inductance under the unsaturation state, L_{ld} represents a direct-axis leakage magnetic flux linkage, L_{mq,u} represents a quadrature-axis mutual inductance under the unsaturation state, L_{lq} represents a quadrature-axis leakage magnetic flux linkage, L_{kneel,d} represents the first d-component of magnetic flux linkage at the knee point, and L_{kneel,q} represents the first q-component of magnetic flux linkage at the knee point. The parameters of the synchronous motor comprises: a saturation parameter of the synchronous motor b, a field current i_{f}, a current i_{D} of a direct-axis damping winding D, a current i_{g} of a quadrature-axis damping winding g, and a current i_{Q} of another quadrature-axis damping winding Q. iᵣ represents a rotor current matrix.

$${L}_{ss}^{dq 0}$$

represents a stator self-inductance matrix of the synchronous motor under the dq0 reference frame. Rₛ represents a stator resistance matrix of the synchronous motor. k is equal to 2/Δt.

$${L}_{s r}^{dq 0}$$

represents a stator-rotor mutual-inductance matrix of the synchronous motor under the dq0 reference frame. îₛ represents a stator current matrix obtained in an immediately previous time step. [symbol] represents a stator voltage matrix obtained in the immediately previous time step. [symbol] represents a phase domain matrix of a stator magnetic flux linkage obtained in the immediately previous time step.

In an embodiment, in step S3, the equivalent resistance matrix R_{equiv} is constructed according to the Thevenin equation, and the inverse of the equivalent resistance matrix is calculated to obtain the equivalent conductance matrix. Before entering a next cycle for the next step, the first current, the second current, and the third current of the three phases, and the equivalent conductance matrix, are all inputted into a network equation, and the network equation is solved to obtain the a-phase voltage, the b-phase voltage, and the c-phase voltage.

It should be noted that the equivalent resistance matrix is constructed as follows.

$$[ {R}_{equiv} ] = [ \begin{matrix}{R}_{s} & {R}_{m} & {R}_{m} \\ {R}_{m} & {R}_{s} & {R}_{m} \\ {R}_{m} & {R}_{m} & {R}_{s}\end{matrix} ]$$

$${R}_{m} = ( {R}_{0} - {R}_{ave} ) / 3$$

$${R}_{s} = ( {R}_{0} + 2 {R}_{ave} ) / 3$$

In an embodiment, determining the second d-component and the second q-component of magnetic flux linkage at the knee point of the synchronous motor according to the d-component of the stator magnetic flux linkage, the q-component of the stator magnetic flux linkage, and the magnetic flux linkage at the knee point comprises followings steps.

A d-component of an air-gap magnetic flux linkage and a q-axis component of the air-gap magnetic flux linkage are determined according to parameters of the synchronous motor, the first d-component of magnetic flux linkage at the knee point, the first q-component of magnetic flux linkage at the knee point, the second q-component of the armature current, and the second d-component of the armature current. A deflection angle of magnetic flux linkage at the knee point is determined through an inverse trigonometric function according to a ratio of the q-component of the air-gap magnetic flux linkage to the d-component of the air-gap magnetic flux linkage.

The second d-component of magnetic flux linkage at the knee point and the second q-component of magnetic flux linkage at the knee point are determined through a trigonometric function according to the magnetic flux linkage at the knee point and the deflection angle of magnetic flux linkage at the knee point.

Equations for determining the d-component λ_{md} and the q-component α_{mq} of the air-gap magnetic flux linkage may be as follows.

$${λ}_{md} = {bL}_{md ,} {}_{u} {i}_{s 2}^{d} + \frac{\sqrt{2}}{\sqrt{3}} b {L}_{m d} , {}_{u} {i}_{f} + \frac{\sqrt{2}}{\sqrt{3}} {bL}_{m d} , {}_{u} {i}_{D} + {λ}_{kneel , d}$$

$${λ}_{mq} = {bL}_{mq ,} {}_{u} {i}_{s 2}^{q} + \frac{\sqrt{2}}{\sqrt{3}} b {L}_{mq} , {}_{u} {i}_{g} + \frac{\sqrt{2}}{\sqrt{3}} {bL}_{mq} , {}_{u} {i}_{Q} + {λ}_{kneel , q}$$

The inverse trigonometric function equation for calculating the deflection angle of the flux linkage at the knee point may be: β=tan⁻¹(λ_{mq}/λ_{md}). Equations for calculating the second d-component λ_{knee2, d} and the second q-component λ_{knee2, q} of the magnetic flux linkage at the knee point may be: λ_{knee2, d}=λₖₙₑₑ cos β, λ_{knee2, q}=λₖₙₑₑ sin β, where λₖₙₑₑ represents the magnetic flux linkage at the knee point. There are following relationships.

$${λ}_{sk}^{dq 0} = {[ \begin{matrix}{λ}_{k n e e} {,}_{d} & {λ}_{k n e e} {,}_{q} & 0\end{matrix} ]}^{T} ; {λ}_{r k} = {[ \begin{matrix}{λ}_{k n e e} {,}_{d} & {λ}_{k n e e} {,}_{d} & {λ}_{k n e e} {,}_{q} & {λ}_{k n e e} {,}_{q}\end{matrix} ]}^{T}$$

In an embodiment, the method further comprises a following step. In a case that the magnetic flux linkage of the air gap is greater than or equal to an air-gap magnetic-flux-linkage threshold, the q-component of the air-gap magnetic flux linkage, the d-component of the air-gap magnetic flux linkage, and the magnetic flux linkage of the air gap are corrected according to a saturation correction parameter to update the d-component of the stator magnetic flux linkage and the q-component of the stator magnetic flux linkage.

The magnetic flux linkage of the air gap being greater than the air-gap magnetic-flux-linkage threshold indicates that the synchronous motor is in the saturation state, and the saturation parameter b of the synchronous motor is equal to the value for the case of the synchronous motor being in the saturation state. That is, in an embodiment as shown in FIG. 2, there is b=Mₛₗₒₚₑ/M_{du}. An inductance matrix L^{dq0} of a synchronous motor is corrected according to the saturation parameter b to obtain corrected values of the two parameters L_{md,u} and L_{mq,u}, and these two corrected values are inputted into the equations for calculating the d-component λ_{md} and the q-component λ_{mq} of the air-gap magnetic flux linkage to obtain a corrected d-component λ_{md} and a corrected q-component λ_{mq} of the air-gap magnetic flux linkage. Thereby, the magnetic flux linkage of the air gap is updated.

In the method provided herein, an equation of Norton equivalent circuit for the synchronous motor can be established (in step S2) only through predicting the armature current and the d-component and the q-component of magnetic flux linkage of the knee point, without predicting a rotating electromotive force. Hence, a cumulative error in the predicted quantities is avoided, improving the simulation accuracy. In steps S2 and S3, the Park transformation is performed on the phase-domain discrete model of the synchronous motor, which ensures that the equivalent resistance matrix in the equation of Norton equivalent circuit of the synchronous motor is a constant matrix. The equivalent resistance matrix is modified and the trigonometric calculate are performed again for updating the air-gap magnetic flux linkage, only when the synchronous motor enters or exits the saturation state, which ensures computing efficiency of the dq0 models. In step S5, the simulation proceeds to a next step only when the air-gap magnetic flux linkage is not greater than the air-gap magnetic flux linkage threshold. In comparison with modeling electromagnetic transients without considering the magnetic saturation, the method provided herein improves accuracy of modeling steady-states and transient states of the synchronous motor.

### Second Embodiment

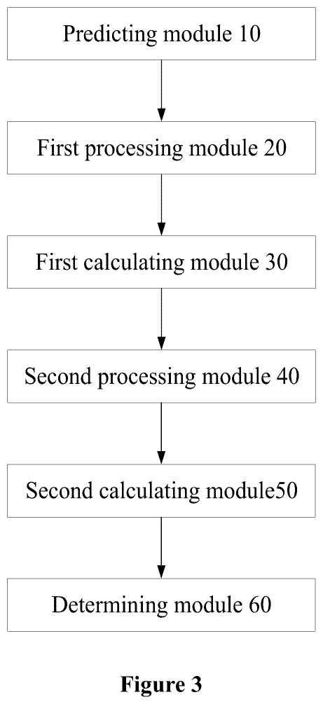

FIG. 3 is a block diagram of a system for modeling electromagnetic transients of a synchronous motor based on magnetic saturation according to an embodiment of the present disclosure.

Reference is made to FIG. 3. In an embodiment, a system for electromagnetic transients of a synchronous motor based on magnetic saturation comprises a predicting module 10, a first processing module 20, a first calculating module 30, a second processing module 40, a second calculating module 50, and a determining module 60.

The predicting module is configured to: predict a first rotor angular velocity, a first rotor angle, a first quadrature-axis component (q-component) of an armature current, a direct-axis component (d-component) of the armature current, a first d-component of magnetic flux linkage at a knee point of a magnetic-flux-linkage curve, and a first q-component of magnetic flux linkage at the knee point, of the synchronous motor at a given moment through linear extrapolation; and obtain magnetic flux linkage at the knee point indicating transition between an unsaturated state and a saturated state of the synchronous motor.

The first processing module is configured to: determine a first equation of Norton equivalent circuit for simulating the synchronous motor according to the first q-component of the armature current and the first current d-component of the armature current; and transform the first equation of Norton equivalent circuit expressed in a direct-quadrature-zero (dq0) reference frame into a second equation of Norton equivalent circuit expressed in a three-phase (abc) reference frame through coordinate transformation.

The first calculating module is configured to: determine an equivalent conductance matrix, which is an inverse of an equivalent resistance matrix in the second equation of Norton equivalent circuit; and solve a network conductance matrix, through substituting the determined equivalent conductance matrix into the network conductance matrix, to obtain three phase-voltages at ports of the synchronous motor.

The second processing module is configured to: determine, according to the three phase-voltages, a second q-component and a second d-component of the armature current of the synchronous motor and a rotor current of the synchronous motor; and determine a d-component of a stator magnetic flux linkage, a q-component of the stator magnetic flux linkage, and magnetic flux linkage of an air gap, of the synchronous motor according to the second q-component of the armature current, the second d-component of the armature current, the first d-component of magnetic flux linkage at the knee point, and the first q-component of magnetic flux linkage at the knee point.

The second calculating module is configured to, in response to the magnetic flux linkage of the air gap being less than or equal to an air-gap magnetic-flux-linkage threshold: solve a mechanical system equation, through substituting the second q-component of the armature current, the second d-component of the armature current, the d-component of the stator magnetic flux linkage, and the q-component of the stator magnetic flux linkage into the mechanical system equation, to obtain a second rotor angular velocity and a second rotor angle of the synchronous motor; and determine a second d-component and a second q-component of magnetic flux linkage at the knee point of the synchronous motor according to the d-component of the stator magnetic flux linkage, the q-component of the stator magnetic flux linkage, and the magnetic flux linkage at the knee point.

The determining module is configured to: determine absolute differences between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively; and output the second rotor angular velocity and the second rotor angle in response to each of the absolute differences being smaller than a respective difference threshold of said absolute difference.

In an embodiment, the mechanical system equation is as follows.

$${T}_{gen} = \frac{p}{2} ( {λ}_{d} {i}_{s 2}^{q} - {λ}_{q} {i}_{s 2}^{d} )$$

$$ω = \frac{d θ}{dt}$$

$$J \frac{d ω}{d t} + D ω = T - {T}_{gen}$$

p represents a number of poles in the synchronous motor, λ_{q} represents the q-component of the stator magnetic flux linkage, λ_{d} represents the d-component of the stator magnetic flux linkage,

$${i}_{s 2}^{d}$$

represents the second d-component,

$${i}_{s 2}^{q}$$

represents the second q-component, J represents rotational inertia of the synchronous motor, D represents a coefficient of viscosity and air-damping of the synchronous motor in air, T represents a mechanical torque of the synchronous motor, ω represents the second rotor angular velocity, θ represents the second rotor angle, and t represents time in simulation.

Details of the modules in the system have been illustrated in steps of the foregoing method embodiments, and hence the details would not be repeated herein for the second embodiment.

### Third Embodiment

A device for modeling electromagnetic transients of a synchronous motor based on magnetic saturation is further provided according to an embodiment of the present disclosure. The device comprises a processor and a memory.

The memory is configured to store program codes and transmit the program codes to the processor.

The processor is configured to execute instructions in the program codes to perform the foregoing method according to any foregoing embodiment.

The method for modeling electromagnetic transients of a high-efficiency synchronous motor has been described in detail according to the first embodiment of the present disclosure, and hence would not be repeated herein. The processor is configured to execute the steps in the foregoing method embodiments according to instructions in the program codes. Alternatively, the processor when executing a computer program may implement the function of each module/unit in any foregoing system/apparatus embodiments.

As an example, the computer program may be partitioned into one or more modules/units, and the one or more modules/units are stored in the memory and are executed by the processor to implement technical solutions of the present disclosure. The one or more modules/units may refer to a series of instruction segments of a computer program capable of implementing specific functions. The instruction segments are capable of describing a process of executing the computer program in a terminal device.

The terminal device can be a computing device, such as a desktop computer, a laptop, a palmtop, or a cloud server. The terminal device may comprise, but is not limited to, a processor and a memory. Those skilled in the art can understand that the terminal is not limited thereto. In comparison with what is shown in the drawings, the terminal device may comprise more or fewer components, a combination of some components, or different components. For example, the terminal device may further comprise I/O devices, a network access device, a bus, or the like.

The processor may be a central processing unit (CPU), a general-purpose processor, a digital signal processor (DSP), an application specific integrated circuit (ASIC), a field-programmable gate array (FPGA), any other programmable logic device, a discrete gate, a transistor logic device, a discrete hardware component, etc. The general processor may be a microprocessor, a conventional processor, or the like.

The memory may be an internal storage unit of a terminal device, such as a hard disk or a memory of the terminal device. The memory may be an external storage device outside of the terminal device, such as a plug-in hard disk, a smart media card (SMC), a secure digital (SD) card, or a flash card, which is capable of being coupled to the terminal device. Furthermore, the memory may comprise the internal storage unit of the terminal device and the external storage device. The memory is configured to store the computer program and other programs and data required by the terminal device. The memory may further store temporarily data that has been output or is to be output.

For the sake of convenience and brevity of description, a detailed working process of the system, the device, and the units may refer to a corresponding process in the method embodiments and is not repeated herein.

The system, the device, and the method according to embodiments of the present disclosure may be implemented in other manners. For example, the device embodiments described above are only illustrative. For example, the delimitation of the units is on a basis logical functions, and they may be delimited otherwise in practice. For example, multiple units or components may be combined or may be integrated into another system, or some features may be omitted or may be not implemented. In addition, mutual coupling, direct coupling, and communication connection as shown or discussed above may be indirect coupling or communication connection implemented via an interface, an apparatus, or a unit, which may be electrical, mechanical, or in other forms.

The units described as separate components may be or may not be separated physically, and components displayed as units may be or may not be physical units. That is, the components may be located at a same position or may be distributed among multiple network units. Some or all of the units may be selected according to actual requirements to achieve an objective of the present embodiments.

In addition, the functional units in the embodiments of the present disclosure may be integrated into one processing unit or may be units physically independently. Two or more units may be integrated in one unit. The integrated unit may be implemented in a form of hardware, or in a form of a software function unit.

In a case that the integrated unit is implemented as a software function unit and is sold or used as an independent product, it may be stored in a computer readable storage medium. On a basis of such understanding, an essence or a part contributing to the conventional technology of the technical solutions, or all or a part of the technical solutions of the present disclosure, may be embodied in a form of a software product. The software product may be stored in a storage medium and comprise instructions for enabling a computer device (which may be a personal computer, a server, a network device and so on) to perform all or a part of the steps of the methods according to the embodiments of the present disclosure. The storage medium includes a U disk, a removable hard disk, a read-only memory (ROM), a random-access memory (RAM), a magnetic disk, an optical disk, or another media that can store program codes.

As described above, the above embodiments are only intended to describe the technical solutions of the present disclosure, and not to limit the present disclosure. Although the present disclosure is described in detail with reference to the above embodiments, those skilled in the art should understand that, modifications can be made to the technical solutions recorded in the above embodiments, or equivalent replacements can be made to some of the technical features thereof, and the modifications and the replacements will not make the corresponding technical solutions deviate from the spirit and the scope of the technical solutions of the embodiments of the present disclosure.

1. A method for modeling electromagnetic transients of a synchronous motor based on magnetic saturation, comprising:
step S1,
predicting a first rotor angular velocity, a first rotor angle, a first quadrature-axis component (q-component) of an armature current, a direct-axis component (d-component) of the armature current, a first d-component of magnetic flux linkage at a knee point of a magnetic-flux-linkage curve, and a first q-component of magnetic flux linkage at the knee point, of the synchronous motor at a given moment through linear extrapolation, and
obtaining magnetic flux linkage at the knee point indicating transition between an unsaturated state and a saturated state of the synchronous motor;
step S2,
determining a first equation of Norton equivalent circuit for simulating the synchronous motor according to the first q-component of the armature current and the first current d-component of the armature current, and
transforming the first equation of Norton equivalent circuit expressed in a direct-quadrature-zero (dq0) reference frame into a second equation of Norton equivalent circuit expressed in a three-phase (abc) reference frame through coordinate transformation;
step S3,
determining an equivalent conductance matrix, which is an inverse of an equivalent resistance matrix in the second equation of Norton equivalent circuit, and
solving a network conductance matrix, through substituting the determined equivalent conductance matrix into the network conductance matrix, to obtain three phase-voltages at ports of the synchronous motor;
step S4,
determining, according to the three phase-voltages, a second q-component and a second d-component of the armature current of the synchronous motor and a rotor current of the synchronous motor, and
determining a d-component of a stator magnetic flux linkage, a q-component of the stator magnetic flux linkage, and magnetic flux linkage of an air gap, of the synchronous motor according to the second q-component of the armature current, the second d-component of the armature current, the first d-component of magnetic flux linkage at the knee point, and the first q-component of magnetic flux linkage at the knee point;
step S5, in response to the magnetic flux linkage of the air gap being less than or equal to an air-gap magnetic-flux-linkage threshold,
solving a mechanical system equation, through substituting the second q-component of the armature current, the second d-component of the armature current, the d-component of the stator magnetic flux linkage, and the q-component of the stator magnetic flux linkage into the mechanical system equation, to obtain a second rotor angular velocity and a second rotor angle of the synchronous motor, and
determining a second d-component and a second q-component of magnetic flux linkage at the knee point of the synchronous motor according to the d-component of the stator magnetic flux linkage, the q-component of the stator magnetic flux linkage, and the magnetic flux linkage at the knee point;
step S6,
determining absolute differences between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively, and
returning to the step S1 for a next time step in response to each of the absolute differences being smaller than a respective difference threshold of said absolute difference.

2. The method according to claim 1, further comprising:
returning to the step S4 in response to any of the absolute differences being not smaller than the respective difference threshold of said absolute difference.

3. The method according to claim 1, wherein determining the second d-component and the second q-component of magnetic flux linkage at the knee point of the synchronous motor according to the d-component of the stator magnetic flux linkage, the q-component of the stator magnetic flux linkage, and the magnetic flux linkage at the knee point comprises:
determining a d-component of an air-gap magnetic flux linkage and a q-axis component of the air-gap magnetic flux linkage according to parameters of the synchronous motor, the first d-component of magnetic flux linkage at the knee point, the first q-component of magnetic flux linkage at the knee point, the second q-component of the armature current, and the second d-component of the armature current;
determining a deflection angle of magnetic flux linkage at the knee point through an inverse trigonometric function according to a ratio of the q-component of the air-gap magnetic flux linkage to the d-component of the air-gap magnetic flux linkage; and
determining the second d-component of magnetic flux linkage at the knee point and the second q-component of magnetic flux linkage at the knee point through a trigonometric function according to the magnetic flux linkage at the knee point and the deflection angle of magnetic flux linkage at the knee point.

4. The method according to claim 3, further comprising:
in response to the magnetic flux linkage of the air gap being greater than or equal to an air-gap magnetic-flux-linkage threshold, correcting the q-component of the air-gap magnetic flux linkage, the d-component of the air-gap magnetic flux linkage, and the magnetic flux linkage of the air gap according to a saturation correction parameter to update the d-component of the stator magnetic flux linkage and the q-component of the stator magnetic flux linkage.

5. The method according to claim 1, wherein the mechanical system equation is:
$${T}_{gen} = \frac{p}{2} ( {λ}_{d} {i}_{s 2}^{q} - {λ}_{q} {i}_{s 2}^{d} )$$
$$ω = \frac{d θ}{dt}$$
$$J \frac{d ω}{dt} + D ω = T - {T}_{gen} ,$$
wherein p represents a number of poles in the synchronous motor, λ_{q} represents the q-component of the stator magnetic flux linkage, λ_{d} represents the d-component of the stator magnetic flux linkage,
$${i}_{s 2}^{d}$$
represents the second d-component,
$${i}_{s 2}^{q}$$
represents the second q-component, J represents rotational inertia of the synchronous motor, D represents a coefficient of viscosity and air-damping of the synchronous motor in air, T represents a mechanical torque of the synchronous motor, ω represents the second rotor angular velocity, θ represents the second rotor angle, and t represents time in simulation.

6. The method according to claim 1, wherein determining the first equation of Norton equivalent circuit for simulating the synchronous motor according to the first q-component of the armature current and the first current d-component of the armature current, and transforming the first equation of Norton equivalent circuit expressed in the dq0 reference frame into the second equation of Norton equivalent circuit expressed in the abc reference frame through coordinate transformation, comprises:
obtaining a stator-rotor voltage equation of the synchronous motor, and discretizing the stator-rotor voltage equation through an implicit trapezoidal rule to obtain a first transformation equation;
performing Park transformation on the first transformation equation, eliminating a rotor variable in the first transformation equation, and using average resistance for a direct-axis and a quadrature-axis, to obtain a Thevenin equation for a stator;
transforming the Thevenin equation for the stator to the first equation of Norton equivalent circuit; and
transforming the first equation of Norton equivalent circuit expressed in the dq0 reference frame into the second equation of Norton equivalent circuit expressed in the abc reference frame through phasor coordinate transformation;
wherein first equation of Norton equivalent circuit is:
$${i}_{d , source} = \frac{{e}_{d , mod}}{{R}_{ave}} ;$$
$${i}_{q , source} = \frac{{e}_{q , mod}}{{R}_{ave}} ;$$
$${i}_{0 , source} = \frac{{e}_{0}}{{R}_{0}}$$
$${R}_{ave} = ( {R}_{d} + {R}_{q} ) / 2 ;$$
$${e}_{d , mod} = {e}_{d} - \frac{{R}_{d} - {R}_{q}}{2} {i}_{s 1}^{d} ;$$
$${e}_{q , mod} = {e}_{q} - \frac{{R}_{d} - {R}_{q}}{2} {i}_{s 1}^{q} ,$$
wherein the phasor coordinate transformation formula is:
$$[ \begin{matrix}{i}_{a , source} \\ {i}_{b , source} \\ {i}_{c , source}\end{matrix} ] = \frac{\sqrt{2}}{\sqrt{3}} [ \begin{matrix}cos {θ}_{1} & sin {θ}_{1} & \frac{1}{\sqrt{2}} \\ cos ( {θ}_{1} - 120 ° ) & sin ( {θ}_{1} - 120 ° ) & \frac{1}{\sqrt{2}} \\ cos ( {θ}_{1} + 120 ° ) & sin ( {θ}_{1} + 120 ° ) & \frac{1}{\sqrt{2}}\end{matrix} ] [ \begin{matrix}{i}_{d , source} \\ {i}_{q , source} \\ {i}_{0 , source}\end{matrix} ] ,$$
wherein
$${i}_{s 1}^{d}$$
represents the first d-component of the armature current,
$${i}_{s 1}^{q}$$
represents the first q-component of the armature current, R_{d}, R_{q} and R₀ are resistance parameters in a resistance matrix in the Thevenin equation, e_{d}, e_{q} and e₀ are voltage parameters in a voltage-source matrix in the Thevenin equation, i_{d, source} represents a first current of a direct-axis in first equation of Norton equivalent circuit, i_{q, source} represents a second current of a quadrature-axis in the first equation of Norton equivalent circuit, i_{0, source} represents a third current of a zero component in the first equation of Norton equivalent circuit, θ₁ represents a first rotor angle, i_{a, source} represents a first current of an a-phase current source in the second equation of Norton equivalent circuit, i_{b, source} represents a second current of a b-phase current source in the second equation of Norton equivalent circuit, and i_{c, source} represents a third current of a c-phase current source in a second equation of Norton equivalent circuit.

7. The method according to claim 1, wherein determining, according to the three phase-voltages, the second q-component and the second d-component of the armature current of the synchronous motor and a rotor current of the synchronous motor, and determining the d-component of a stator magnetic flux linkage, the q-component of the stator magnetic flux linkage, and the magnetic flux linkage of an air gap, of the synchronous motor according to the second q-component of the armature current, the second d-component of the armature current, the first d-component of magnetic flux linkage at the knee point, and the first q-component of magnetic flux linkage at the knee point, comprises:
performing Park transformation on the three phase-voltages to obtain voltage components of a direct-axis, a quadrature-axis, and a zero sequence;
calculating the second q-component of the armature current and the second d-component of the armature current according to matrix parameters of a Thevenin equation for a stator and the voltage components through an armature-current calculation equation;
calculating the rotor current according to parameters of the synchronous motor, the voltage components, the second q-component of the armature current, and the second d-component of the armature current through a rotor-current calculation equation;
calculating the d-component and the q-component of the stator magnetic flux linkage according to the parameters of the synchronous motor, the second q-component of the armature current, the second d-component of the armature current, the first d-component of magnetic flux linkage at the knee point, and the first q-component of magnetic flux linkage at the knee point, through a stator-flux-linkage-component calculation equation;
wherein the Park transformation is implemented through:
$$[ \begin{matrix}{v}_{d} \\ {v}_{q} \\ {v}_{0}\end{matrix} ] = \frac{\sqrt{2}}{\sqrt{3}} [ \begin{matrix}cos {θ}_{1} & cos ( {θ}_{1} - 120 ° ) & cos ( {θ}_{1} + 120 ° ) \\ sin {θ}_{1} & sin ( {θ}_{1} - 120 ° ) & sin ( {θ}_{1} + 120 ° ) \\ \frac{1}{\sqrt{2}} & \frac{1}{\sqrt{2}} & \frac{1}{\sqrt{2}}\end{matrix} ] [ \begin{matrix}{v}_{a} \\ {v}_{b} \\ {v}_{c}\end{matrix} ] ,$$
wherein the armature-current calculation equation is:
$${i}_{s 2}^{d} = ( {e}_{d , mod} - {v}_{d} ) / {R}_{ave} ;$$
$${i}_{s 2}^{q} = ( {e}_{q , mod} - {v}_{q} ) / {R}_{ave} ;$$
$${i}_{s 2}^{0} = ( {e}_{0} - {v}_{0} ) / {R}_{0}$$
$${R}_{ave} = ( {R}_{d} + {R}_{q} ) / 2 ;$$
$${e}_{d , mod} = {e}_{d} - \frac{{R}_{d} - {R}_{q}}{2} {i}_{s 1}^{d} ;$$
$${e}_{q , mod} = {e}_{q} - \frac{{R}_{d} - {R}_{q}}{2} {i}_{s 1}^{q} ,$$
wherein the rotor-current calculation equation is:
$${i}_{r} = {R}_{sr}^{dq {0}^{- 1}} ( \begin{matrix}{P}^{- 1} {h}_{s}^{PD} & - {v}_{s}^{dq 0} & - {R}_{ss}^{dq 0} & {i}_{s}^{dq 0}\end{matrix} ) ;$$
$${i}_{r} = {[ \begin{matrix}{i}_{f} & {i}_{D} & {i}_{g} & {i}_{Q}\end{matrix} ]}^{T}$$
$${v}_{s}^{dq 0} = {[ \begin{matrix}{v}_{d} & {v}_{q} & {v}_{0}\end{matrix} ]}^{T}$$
$${i}_{s}^{dq 0} = {[ \begin{matrix}{i}_{s 2}^{d} & {i}_{s 2}^{q} & {i}_{0}\end{matrix} ]}^{T}$$
$${h}_{s}^{PD} = - {R}_{s} {\hat{i}}_{s} + k {\hat{λ}}_{s} - {\hat{v}}_{s}$$
$$P = \frac{\sqrt{2}}{\sqrt{3}} [ \begin{matrix}cos {θ}_{1} & cos ( {θ}_{1} - 120 ° ) & cos ( {θ}_{1} + 120 ° ) \\ sin {θ}_{1} & sin ( {θ}_{1} - 120 ° ) & sin ( {θ}_{1} + 120 ° ) \\ \frac{1}{\sqrt{2}} & \frac{1}{\sqrt{2}} & \frac{1}{\sqrt{2}}\end{matrix} ]$$
$${R}_{ss}^{dq 0} = {R}_{s} + {kL}_{ss}^{dq 0} ;$$
$${R}_{sr}^{dq 0} = {kL}_{sr}^{dq 0} ,$$
wherein the stator-flux-linkage-component calculation equation is:
$${λ}_{d} = {λ}_{ld} + {λ}_{md} ;$$
$${λ}_{q} = {λ}_{lq} + {λ}_{mq} ;$$
$${λ}_{m} = \sqrt{{λ}_{md}^{2} + {λ}_{mq}^{2}}$$
$${λ}_{ld} = {L}_{ld} {i}_{s 2}^{d} ;$$
$${λ}_{md} = {bL}_{md , u} {i}_{s 2}^{d} + \frac{\sqrt{2}}{\sqrt{3}} {bL}_{md , u} {i}_{f} + \frac{\sqrt{2}}{\sqrt{3}} {bL}_{md , u} {i}_{D} + {λ}_{knee 1 , d}$$
$${λ}_{lq} = {L}_{ld} {i}_{s 2}^{q} ;$$
$${λ}_{mq} = {bL}_{mq , u} {i}_{s 2}^{q} + \frac{\sqrt{2}}{\sqrt{3}} {bL}_{mq , u} {i}_{g} + \frac{\sqrt{2}}{\sqrt{3}} {bL}_{mq , u} {i}_{Q} + {λ}_{knee 1 , q} ,$$
wherein
$${i}_{s 2}^{d}$$
represents the second d-component,
$${i}_{s 2}^{q}$$
represents the second q-component of a second current, R_{d}, R_{q} and R₀ are resistance parameters in a resistance matrix in the Thevenin equation, e_{d}, eq and e₀ are voltage parameters in a voltage-source matrix in the Thevenin equation for the stator, θ₁ represents the first rotor angle, vₐ represents a voltage of an a-phase in the three phase-voltages, v_{b} represents a voltage of a b-phase in the three phase-voltages, v_{c} represents a voltage of a c-phase in the three phase-voltages, v_{d} represents a first voltage on the d-axis among the voltage components, v_{q} represents a second voltage on the q-axis among the voltage components, v₀ represents a third voltage on the zero sequence among the voltage components, λ_{d} represents the d-component of the stator magnetic flux linkage, λ_{q} represents the q-component of the stator magnetic flux linkage, λₘ represents the magnetic flux linkage of the air gap, λ_{md} represents the d-component of the air-gap magnetic flux linkage, λ_{mq} represents the q-component of the air-gap magnetic flux linkage, λ_{lq} represents a q-component of a leakage magnetic flux linkage, λ_{ld} represents a d-component of the leakage magnetic flux linkage, L_{md,u} represents a direct-axis mutual inductance under the unsaturation state, L_{ld} represents a direct-axis leakage magnetic flux linkage, L_{mq,u} represents a quadrature-axis mutual inductance under the unsaturation state, L_{lq} represents a quadrature-axis leakage magnetic flux linkage, L_{kneel,d} represents the first d-component of magnetic flux linkage at the knee point, and L_{kneel,q} represents the first q-component of magnetic flux linkage at the knee point;
wherein the parameters of the synchronous motor comprises: a saturation parameter of the synchronous motor b, a field current i_{f}, a current i_{D} of a direct-axis damping winding D, a current i_{g} of a quadrature-axis damping winding g, and a current i_{Q} of another quadrature-axis damping winding Q; and
wherein iᵣ represents a rotor current matrix,
$${L}_{ss}^{dq 0}$$
represents a stator resistance matrix of the synchronous motor under the dq0 reference frame, Rₛ represents a stator resistance matrix of the synchronous motor, k is equal to 2/Δt,
$${L}_{sr}^{dq 0}$$
represents a stator-rotor mutual-inductance matrix of the synchronous motor under the dq0 reference frame, îₛ represents a stator current matrix obtained in a immediately previous time step, [symbol] represents a stator voltage matrix obtained in the immediately previous time step, and [symbol] represents a phase domain matrix of a stator magnetic flux linkage obtained in the immediately previous time step.

8. The method according to claim 1, wherein determining the equivalent conductance matrix, which is the inverse of the equivalent resistance matrix in the second equation of Norton equivalent circuit, and solving the network conductance matrix, through substituting the determined equivalent conductance matrix into the network conductance matrix, to obtain three phase-voltages at ports of the synchronous motor, comprises:
calculating the inverse of the equivalent resistance matrix in the second equation of Norton equivalent circuit to obtain the equivalent conductance matrix;
inputting, before the next time step, the obtained equivalent conductance matrix into the network conductance matrix; and
solving the network conductance matrix through a network solving equation to obtain the three phase-voltages;
wherein the network solving equation is YV=1, Y represents the network conductance matrix, I represents a current matrix comprising current parameters in the second equation of Norton equivalent circuit, and V represents a voltage matrix comprising the three phase-voltages.

9. A system for modeling electromagnetic transients of a synchronous motor based on magnetic saturation, comprising:
a predicting module, configured to:
predict a first rotor angular velocity, a first rotor angle, a first quadrature-axis component (q-component) of an armature current, a direct-axis component (d-component) of the armature current, a first d-component of magnetic flux linkage at a knee point of a magnetic-flux-linkage curve, and a first q-component of magnetic flux linkage at the knee point, of the synchronous motor at a given moment through linear extrapolation, and
obtain magnetic flux linkage at the knee point indicating transition between an unsaturated state and a saturated state of the synchronous motor;
a first processing module, configured to:
determine a first equation of Norton equivalent circuit for simulating the synchronous motor according to the first q-component of the armature current and the first current d-component of the armature current, and
transform the first equation of Norton equivalent circuit expressed in a direct-quadrature-zero (dq0) reference frame into a second equation of Norton equivalent circuit expressed in a three-phase (abc) reference frame through coordinate transformation;
a first calculating module, configured to:
determine an equivalent conductance matrix, which is an inverse of an equivalent resistance matrix in the second equation of Norton equivalent circuit, and
solve a network conductance matrix, through substituting the determined equivalent conductance matrix into the network conductance matrix, to obtain three phase-voltages at ports of the synchronous motor;
a second processing module, configured to:
determine, according to the three phase-voltages, a second q-component and a second d-component of the armature current of the synchronous motor and a rotor current of the synchronous motor, and
determine a d-component of a stator magnetic flux linkage, a q-component of the stator magnetic flux linkage, and magnetic flux linkage of an air gap, of the synchronous motor according to the second q-component of the armature current, the second d-component of the armature current, the first d-component of magnetic flux linkage at the knee point, and the first q-component of magnetic flux linkage at the knee point;
a second calculating module, configured to, in response to the magnetic flux linkage of the air gap being less than or equal to an air-gap magnetic-flux-linkage threshold:
solve a mechanical system equation, through substituting the second q-component of the armature current, the second d-component of the armature current, the d-component of the stator magnetic flux linkage, and the q-component of the stator magnetic flux linkage into the mechanical system equation, to obtain a second rotor angular velocity and a second rotor angle of the synchronous motor, and
determine a second d-component and a second q-component of magnetic flux linkage at the knee point of the synchronous motor according to the d-component of the stator magnetic flux linkage, the q-component of the stator magnetic flux linkage, and the magnetic flux linkage at the knee point;
a determining module, configured to:
determine absolute differences between the second q-component of the armature current and the first q-component of the armature current, between the second d-component of the armature current and the first d-component of the armature current, between the second rotor angular velocity and the first rotor angular velocity, between the second rotor angle and the first rotor angle, between the second d-component of magnetic flux linkage at the knee point and the first d-component of magnetic flux linkage at the knee point, and between the second q-component of magnetic flux linkage at the knee point and the second q-component of magnetic flux linkage at the knee point, respectively, and
output the second rotor angular velocity and the second rotor angle in response to each of the absolute differences being smaller than a respective difference threshold of said absolute difference.

10. A terminal device, comprising a processor and a memory, wherein:
the memory is configured to store program codes and transmit the program codes to the processor, and
the processor is configured to execute instructions in the program codes to perform the method according to claim 1.

11. A non-transitory computer-readable storage medium, storing program codes, wherein the program codes when executed by a processor implements the method according to claim 1.

12. A method for fabricating a synchronous motor, comprising:
obtaining original parameters for fabricating a synchronous motor;
establishing a model simulating the synchronous motor through the method according to claim 1;
adjusting the original parameters according to operation of the simulated synchronous motor in the model to obtain adjusted parameters; and
fabricating the synchronous motor according to the adjusted parameters.
